(19) United States
(12) Patent Application Publication
(10) Pub. No.: US 2004/0161117 A1
(43) Pub. Date: Aug. 19, 2004

(54) Method for at least two audio signals

(76) Inventors: Roelof E Reusens, Hasselt (BE); Jean-Christophe Lallemand, Leuven (BE); Raf Coomans, Leuven (BE); Sandrine Laurence Yael Resler, Leuven (BE)

Correspondence Address: Edward W Goodman, US Philips Corporation, Intellectual Property Department, P O Box 3001, Briarcliff Manor, NY, 10510, US

(21) Appl. No.: 10/483,865

(22) PCT Filed: Jul. 3, 2002
(86) PCT No.: PCT/IB02/02797

(30) Foreign Application Priority Data
Jul. 19, 2001 (EP) 012025771.0

(51) Int. Cl. H04R 5/00; H03G 3/00

(52) U.S. Cl. 381/61; 381/1

(57) ABSTRACT

The invention relates to a method for at least two audio signals (A1, A2) each being impressed with a process function, particularly a transformation function. According to the invention, upper values (8) of a function-impressed audio signal (A3) are decreased after the function by a rate and subsequently all values (8, 9) of the partially decreased signal (A4) are increased.

The invention relates to a method for at least two audio signals which are impressed with a process function, particularly a transformation function.

U.S. Pat. No. 5,742,687 discloses a method for a stereo signal in which a filtered left stereo signal is applied to the left loudspeaker of a stereo apparatus and a filtered right stereo signal is applied to the right loudspeaker. A first signal path between the first input and the first output has a first transformation characteristic, and a second signal path between the second input and the second output has a second transformation characteristic. Phase differences lead to an extension of the stereo impression. It may occur that a sound impression at the human ear is reduced although the individual signals of the left and right channel retain their original value.

It is therefore an object of the invention to improve the sound impression at the ear.

This object is achieved by the characteristic features as defined in claim 1. According to the invention, upper values of an audio signal impressed with the function are decreased after the function by a rate, and subsequently all values of the partially decreased signal are increased. When using process methods, particularly transformation methods for sound processing, losses in the output signals, sound pressure and/or acoustic sound impression are generated because of phase-opposed components within the signals of the left and right channel, while the input signals retain their original value. The loss should be compensated by an amplification. When the signal is unfortunately already 0 dB, a digital amplification is not possible without causing interference or saturation. In that case, the signal is compressed by means of a compressor. The compressor properties should be chosen to be such that the input signal of 0 dB generates an output signal whose value is equal to or larger than the desired amplification. The desired amplification results from the loss.

Some audio processes change the acoustic level of the audio signal but do not change the signal level. For example, the signal level remains at 0 dB after a process, but the acoustic level is decreased by −18 dB. The acoustic level is the level observed by persons. In many areas, it is not acceptable that the user experiences this acoustic loss or compensates this loss himself whenever he switches on an acoustic effect. A compensation is possible by changing the adjusted loudspeaker volume. The loss of acoustic level should be compensated by the audio system itself. A simple method is to increase the loudspeaker volume or to amplify the signal. In the example mentioned hereinbefore, the system can raise the loudspeaker volume level to 18 dB. However, this method is not always possible, for example, in a system limited to 0 dB such a compensation may cause clipping of the peaks.

The proposed method is to compress the signal before its amplification so as to avoid clipping of digital peaks. When x dB are required for compensation, the signal is first compressed so that the level maximally reaches −x dB. −x dB should then be achieved when the maximum level is originally 0 dB. Then, the signal is blown up so that the maximum level reaches 0 dB again.

With the compression, the higher signal levels, i.e. the signal levels within a compression zone, are reduced and an effective loss of an acoustic level is experienced. For example, the higher signal levels between −2x dB and 0 dB are effectively reduced by a compression rate of 2 during the compression, whereas smaller signals, i.e. signals of less than −2x dB are left intact. After the x dB amplification, the higher signal levels are reset to a 0-dB limit for which the level compensation is not large enough to compensate the acoustic loss. The higher the signal is originally, the larger the loss. However, the smaller signals are only amplified by x dB so that neither an acoustic loss nor any disturbances occur.

This method allows a compensation without the risk of clipping or disturbing smaller signals while the compression provides the effect for higher signal levels only. For the latter signal levels, a minor acoustic loss will be inevitable. This is actually unavoidable.

Advantageously, the rate for the upper values of the audio signal is two. A suitable compensation between the unchanged range and the decreased range can thereby be achieved.

Advantageously, the upper values are in a range between 0 dB and −40 dB. When using transformation methods for sound processing, losses in the acoustic sound impression of up to 18 dB are generated while the input signals retain their original value, i.e. up to 0 dB. The loss should be compensated by an amplification of 18 dB. A compression is then performed on the signal. The compression properties should be chosen in such a way that the input signal of 0 dB generates an output signal at −18 dB. This can be achieved, for example, with a compression break point at −40 dB and a compression rate of 2.0. The rate is obtained from 1/CR or CF.

In a simple embodiment, a compressor decreases upper values of the function-impressed audio signals at a rate after the process function and before the amplification. The main claim of this method is the use of a compressor for compensating acoustic loss.

These and other aspects of the invention are apparent from and will be elucidated with reference to the embodiments described hereinafter.

In the drawings:

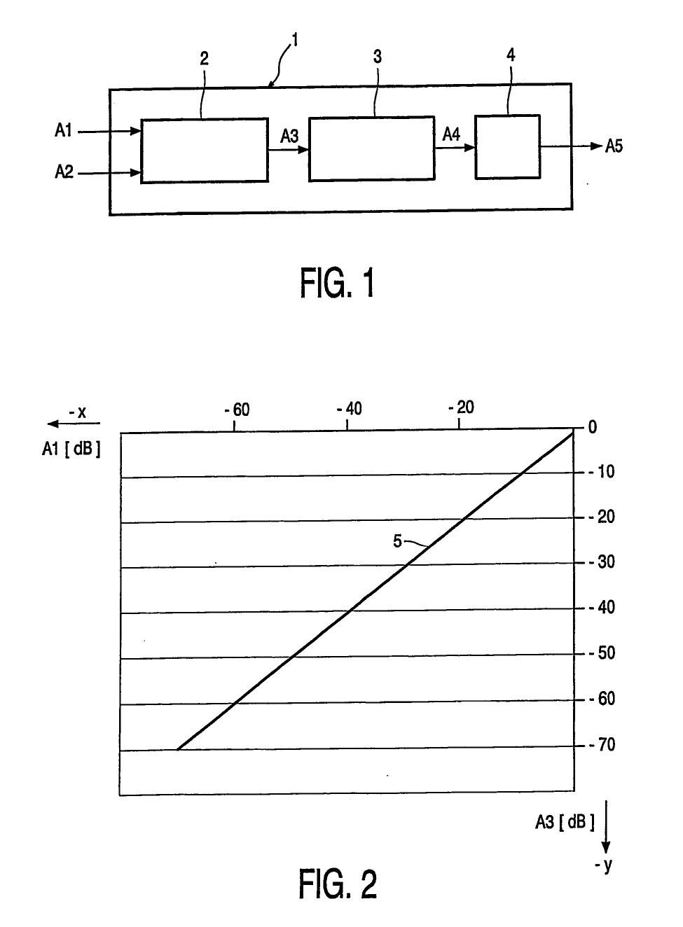

FIG. 1 is a block diagram showing a transformer, a compressor and an amplifier,

FIG. 2 is a diagram of a transformation curve showing an output level of the transformer in dependence upon its input level,

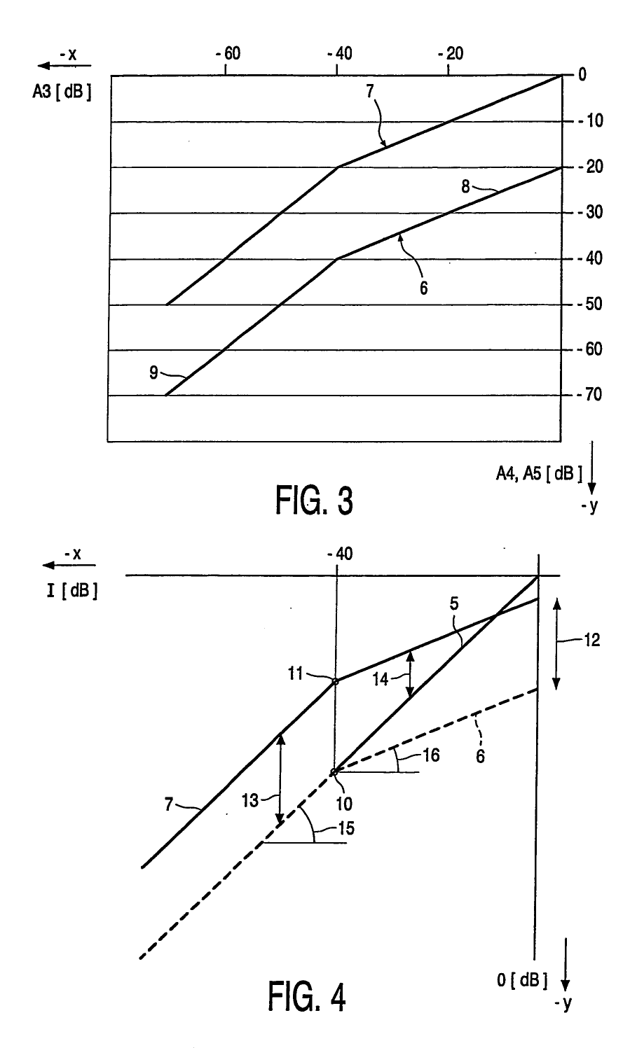

FIG. 3 is a diagram of a compression curve and amplification curve and FIG. 4 is a diagram of all curves.

FIG. 1 shows a circuit arrangement 1 with a transformer 2, a compressor 3 and an amplifier 4. Two audio signals A1 and A2 are applied to the transformer 2 which transforms the audio signals and thus extends the stereo impression. The transformer 2 supplies an output signal A3 which is applied as input signal A3 to the compressor 3. The signal A3 has a signal level of maximally 0 dB and an acoustic level of maximally −x dB. The subsequent compressor 3 decreases peak values of the audio signal A3 in an upper range. The compressor 3 supplies an audio signal A4 which is applied as input signal A4 to the amplifier 4 and has a signal level of maximally −x dB. The amplifier 4 then raises the audio signal A4 by a predetermined level so that the signal A4 has an upper peak value of maximally 0 dB.

FIG. 2 shows a transformation curve 5. Curve 5 shows the output signal A3 in dependence upon the input signal A1 which is filtered with the input signal A2. The signal A1 is the stereo signal of a left channel while the signal A2 is the stereo signal of a right channel. The curve 5 has a ratio of 1:1.

FIG. 3 shows a compression curve 6 and an amplification curve 7. Curve 6 shows the output signal A4 of the compressor 3 in dependence upon the input signal A3 of the compressor 3. The input signal A3 is plotted on the abscissa in the x direction while the output signal A4 is plotted on the ordinate in the y direction. The curve 6 characterizes level 6 of the input signal A3 and the associated level 6 of the output signal A4. The levels 6 are subsequently also denoted as values 6. An upper level range 8 of the curve 6 is decreased by a rate of 2 and extends from −40 dB to 0 dB on the abscissa in the x direction. The level range 8 characterizes upper values 8 of the input signal A3 within the range 8 from −40 dB to 0 dB and its decreased values 8 within the range 8 from −20 to −40 dB of the output signal A4. The upper level range 8 of −40 dB to −20 dB extends on the ordinate in the y direction. As is apparent, the output signal A4 is limited to −20 dB after the compression. Now there is enough room to compensate the 18 dB acoustic loss. In a lower level range 9, input and output signal A3 and A4 are identical.

The amplification curve 7 shows the output signal A5 of the amplifier 4 in dependence upon the input signal A3 of the compressor 3. The output level 6 of the compressor 3 is identical to the input level 6 of the amplifier 4. The amplifier 4 amplifies the signal A4 and raises the overall level 6 by +18 dB.

Curve 5 in FIG. 4 shows the values of the input signal for the transformer 2, curve 6 is the compressed output curve of the compressor 3 and curve 7 is the amplified compressed output curve of the amplifier 4. Output values O (O=output) are plotted in decibels on the ordinate in dependence upon input values I (I=input) on the abscissa. A compression kink 10 in the curve 6 and a compression kink 11 in the curve 7 are at −40 dB. A compensation 12 denotes the increase of the signal by 18 dB. Compression gains 13 and 14 denote the change of values between the signals A3 and A5. An angle 15 is at 45°, an angle 16 is at 22.5° and is characterized by the values 1/CR=CF. R is the electric resistance, C is the capacitance of a capacitor, F stands for Farad.

It can be seen that the loss of sound impression has thus been compensated for input signals which have a level below the compression kink. Above the compression kink, the compensation is smaller as the input signal increases. For an input signal of 0 dB, there is no compensation because a −18 dB room has been used before 18 dB has been amplified. On average, the sound is compensated more or less by 18 dB.

LIST OF REFERENCE NUMERALS

| | |
|---|---|
| 1 | circuit arrangement |
| | transformer |
| 3 | compressor |
| 4 | amplifier |
| 5 | transformation curve |
| 6 | compression curve |
| 7 | amplifier curve |
| 8 | upper range of values |
| 9 | lower range of values |
| 10 | first compression kink |
| 11 | second compression kink |
| 12 | increase |
| 13 | first compression gain |
| 14 | second compression gain |
| 15 | first angle |
| 16 | second angle |

1. A method for at least two audio signals (A1, A2) each being impressed with a process function, particularly a transformation function, characterized in that
upper values (8) of an audio signal (A3) impressed with the function are decreased after the function by a rate and
subsequently all values (8, 9) of the partially decreased signal (A4) are increased.

2. A method as claimed in claim 1, characterized in that the rate for the upper values (8) of the audio signal (A3) is two.

3. A method as claimed in claim 1 and/or 2, characterized in that the upper values (8) are in an upper range (8) of 0 dB to −40 dB.

4. A circuit arrangement (1) for a method for at least two audio signals (A1, A2) each being impressed with a process function, particularly a transformation function, characterized in that a compressor (3) decreases upper values (8) of a function-impressed audio signal (A) by a rate.

5. A circuit arrangement as claimed in claim 4, characterized in that a compressed audio signal (A4) is amplified by means of an amplifier (4).
